(19) United States
(12) Patent Application Publication
(10) Pub. No.: US 2008/0083994 A1
(43) Pub. Date: Apr. 10, 2008

(54) Method for producing a semiconductor component and substrate for carrying out the method

(76) Inventor: Choon Hiang Lim, Johor (MY)

Correspondence Address: SLATER & MATSIL LLP, 17950 PRESTON ROAD, SUITE 1000, DALLAS, TX, 75252, US

(21) Appl. No.: 11/544,288

(22) Filed: Oct. 6, 2006

(51) Int. Cl. H01L 23/28

(52) U.S. Cl. 257/787

(57) ABSTRACT

A semiconductor component includes a substrate (1) having a chip side and a solder ball side. A semiconductor chip (2) is mounted with an adhesive (3) on the chip side of the substrate. The semiconductor chip is electrically conductively connected to a conductor structure of the substrate (1). Ball pads are disposed over the solder ball side of the substrate (1). The ball pads are electrically conductively connected to a conductor structure on the substrate and suitable for application of solder balls (5). The substrate is provided with a bond channel (8). Wire loops (7) are drawn from bond pads on the semiconductor chip to the conductor structure. The substrate is provided with a reservoir (15) at the rim portion. A sealing mold cap (4), made of a mold compound, is provided on the chip-side made of a mold compound and a sealing mold cap projects into the reservoir (15).

### TECHNICAL FIELD

The invention relates to the field of semiconductor production. In various embodiments, the invention relates to the enclosure of semiconductor chips mounted on a carrier substrate with a mold cap.

### BACKGROUND

Methods to mount semiconductor chips on a chip side of a substrate are well known as chip bonding. The semiconductor chip is electrically conductively connected to a conductor structure on the substrate. The substrate is provided with an elongated bond channel to connect bond pads on the semiconductor chip via wire loops with terminals on the other side of the substrate, known as the ball side. The terminals on the substrate are coupled to ball pads by a conductor structure. Solder balls are applied to the ball pads of the conductor structure. The solder ball side is provided with a mask made of a soldering resist.

The chip side of the substrate can be provided with a housing that encloses and protects the semiconductor chip. The housing of the semiconductor chip can be performed with a known mold process. An encapsulation mold for producing the housing is pressed onto the chip side and the encapsulation mold is filled with an encapsulation composition, further called a mold compound. A bond channel on the ball side is filled with the mold compound in a similar manner thereby protecting the wire loops.

During the production of semiconductor components, semiconductor chips are mounted on the mentioned substrates. Such substrates can have multiple chip mounting positions arranged in a matrix like manner. After the mounting process of the chips including the molding process is finished, the substrate is divided into individual semiconductor components, e.g., by sawing or grinding. Each component has a ball side for a later assembling with a printed circuit board.

FBGA housings (FBGA=Fine Ball Grid Array), such as BOC (Board on Chip)—structures, are known for connecting the conductor structures to an external circuitry. In this case, the substrate has a chip side on which the chip or a chip stack is mounted. The substrate has also a solder ball side opposite to the chip side. The conductor structures or parts of the conductor structures are arranged on the solder ball side.

In one embodiment of such housings, the semiconductor chip is mounted face-down with an adhesive onto the chip side of the substrate with its bonding pads directed toward the chip side of the substrate. In this case a bonding channel is provided in the substrate. The bonding channel has preferably the shape of an elongated slot or a quadrangular hole and extends though the substrate. Wire loops are drawn from the bonding pads on the semiconductor chip through the bonding channel to corresponding contact terminals in the conductor structure on the solder ball side for the purpose of electrically connecting the semiconductor chip to the conductive tracks of the conductor structure.

The ball pads of the conductor structure are arranged on the solder ball side. Mentioned ball pads are provided with solder balls via which, in a later process, the semiconductor component can then be mounted and electrically conductively connected to an external circuitry. Such an external circuitry can be, for example, on a printed circuit board. For this purpose, the solder is heated in a reflow process until the temperature rises over the melting temperature. In order to prevent the solder from then flowing away from the ball pads in an uncontrolled manner, the solder ball side is coated with a soldering resist that surrounds each ball pad in a collar-like manner. In this manner, the solder ball avoids such an uncontrolled flowing away of solder during a later mounting process, e.g., a reflow process.

In order to stabilize the entire semiconductor component, the latter is provided with a housing made of a mold compound covering at least the semiconductor chip. The housing comprises an upper housing part on the chip side and—in the case of FBGA housings with a bonding channel—of a lower housing part on the solder ball side.

The encapsulation process is perfomed with an encapsulation mold having the negative shape of the housing parts. Around the negative mold of a housing part, the encapsulation mold is provided with a sealing web. During the production of the housing parts, the encapsulation mold is placed onto the respective substrate side and pressed with a pressure force onto the respective substrate side. In this case, the negative mold encloses the parts of the semiconductor component and the bond channel to be encapsulated. Mold compound is then forced into the negative molds. In this case, the sealing web and the pressure force are intended to prevent mold compound from flowing out of the negative mold.

During the encapsulation process the mold compound is heated to a temperature of approximately 180° C., as a result of which it has very low viscosity and as a result emerges between the substrate side and sealing web.

The result should be a good adhesion between the chip-side mold cap and the substrate on one hand and between the bond channel mold (BC mold) and the substrate on the other hand and is supported only by the interface/interaction of both materials during the mold process. The interface strength is solely depending on both material properties and optimized process interaction as well as the total surface coverage area.

Any mismatch of all mentioned criterias can lead to a mold cap and bond channel mold delamination, e.g., as a result of handling the semiconductor component, may be or can be observed at a later process. Additionally, with adhesive filetting depending on material batch and handling the excessive filetting will further weakening the interface.

FIG. 1 shows a BOC component according to the prior art, based on a substrate 1 and a semiconductor chip 2 mounted on the chip-side of the substrate 1 with an adhesive 3. The semiconductor chip 2 is covered by a mold cap 4 that contacts the substrate 1 at the rim part. The dimensions of the adhesive 3 are a little bigger than the dimensions of the semiconductor chip 2 with the result that a part of the adhesive 3 projects over the rim of the semiconductor chip 2 into the contact area of the mold cap 4 with the substrate 1. FIG. 1A (prior art) illustrates an enlarged part of the component according FIG. 1 with the contact area at the rim part of the substrate in case a delamination has happened. An arrow 10 is directed at the delamination area.

The ball side of the substrate 1 is provided with solder balls 5 mounted on not shown contact pads on the substrate 1. The contact pads are part of a wiring on the substrate 1 and are connected with bond pads 6 on the semiconductor chip 2 via wire loops 7. The wire loops 7 are drawn through a bond channel 8 in the substrate 1, which is filled with a mold compound 9 thus forming a mold cap thereby protecting the wire loops before damage.

FIG. 1B (prior art) shows an enlarged part of the bond channel 8 of the component according to FIG. 1 illustrating the case of bond channel delamination. The arrow 11 is directed at the delaminated part. This delamination is caused by the adhesive bleed into the bond channel 8 during chip bonding caused by pressure force.

With the current design rules, component miniature design is limited. This is because the adhesive/epoxy filetting tolerance needs to be considered into the package size. Otherwise mold cap delamination could be observed.

Additional disadvantages, as well as the singulation speed (dicing step) or the actual equipment technology capacity is not utilized, where lower feed speed is preferred to obtain smooth dicing surface. High speed feed will promote the risk of delamination or the shearing effect on the interface.

### SUMMARY OF THE INVENTION

In one aspect, the invention prevents mold cap delamination during handling of the semiconductor component.

In another aspect, the invention increases the singulation feed speed during a dicing process to use the actual equipment technology capacity.

In yet another aspect, the invention increases the contact force between the mold cap and the substrate on its rim portion.

In another aspect, the invention prevents bleeding of adhesive into the bond channel.

In a further aspect, the invention prevents bond channel delamination during handling.

Embodiments of the invention relate to a semiconductor component with a substrate having a chip side and a solder ball side. A semiconductor chip is mounted with an adhesive on the chip side of the substrate. The semiconductor chip is electrically conductively connected to a conductor structure on the substrate. Ball pads are disposed over the solder ball side of the substrate and the ball pads are electrically conductively connected to a conductor structure on the substrate and suitable for application of solder balls. The substrate is provided with a bond channel to draw wire loops from bond pads on the semiconductor chip to the conductor structure. The substrate is provided with a reservoir at the rim portion. A sealing mold cap is manufactured on the chip-side made of a mold compound and the sealing mold cap projects at least partially into the reservoir.

According to one aspect of the invention, the reservoir is positioned between the circumference of the semiconductor chip and the rim of the substrate.

According to embodiments of the invention, the reservoir has the shape of elongated grooves with an approximately rectangular cross section or any other suitable cross section. The grooves can be manufactured by grinding, drilling, laser treatment or another suitable manufacturing method and are filled with mold compound of the mold cap.

In a variant of the invention, the reservoir is positioned close to the rim of the semiconductor chip partly below the adhesive that extends over the rim of the semiconductor chip. In this case, the reservoir is filled partly with adhesive and mold compound during the mold process.

In another aspect of the invention, the grooves surround the circumference of the semiconductor chip at least partially. The grooves can also be arranged in close position to the comers of the semiconductor chip for a better dicing process.

In other embodiments, the grooves are arranged to surround the whole circumference of the semiconductor chip complete or in sections.

In one refinement, the reservoir in the substrate is positioned near the bond channel underneath the adhesive. The reservoir can have the shape of a groove.

In a further aspect of the invention, the grooves are arranged in parallel to the elongated bond channel that is filled with a mold compound during an encapsulation process and wherein the grooves are filled the adhesive during chip bonding.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a BOC component according the prior art;

FIG. 1A illustrates an enlarged part of the component according FIG. 1 with a delaminated contact area;

FIG. 1B shows an enlarged part of the bond channel of the component according FIG. 1 illustrating the case of BC delamination;

FIG. 2 illustrates an embodiment of the invention provided with a mold cap lock within the substrate;

FIG. 2A is an enlarged view of FIG. 1 showing a mold cap lock;

FIG. 2B shows an enlarged part of FIG. 2 provided with a filetting reservoir;

FIG. 3 illustrates a further embodiment of the invention with BC reservoir close to the bond channel;

FIG. 3A shows an enlarged view of the bond channel;

FIG. 4 shows a chip-side top view with a mold cap lock/reservoir at the rim part of the substrate; and

FIG. 5 depicts an embodiment with a mold cap lock/reservoir near the comers of the chip and additionally provided with a bond channel reservoir.

### DETAILED DESCRIPTION OF ILLUSTRATIVE EMBODIMENTS

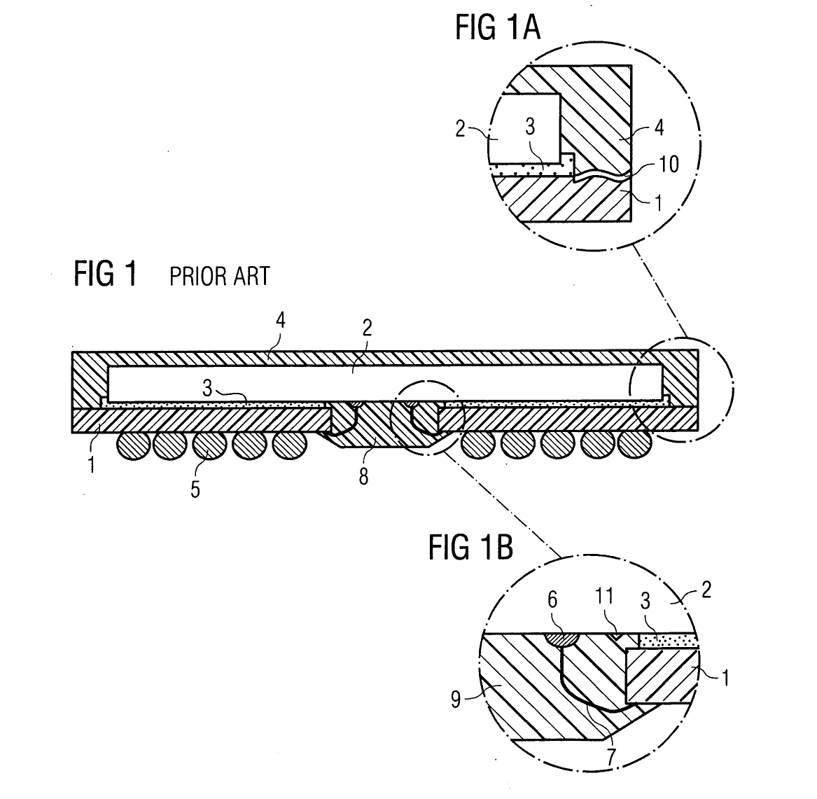

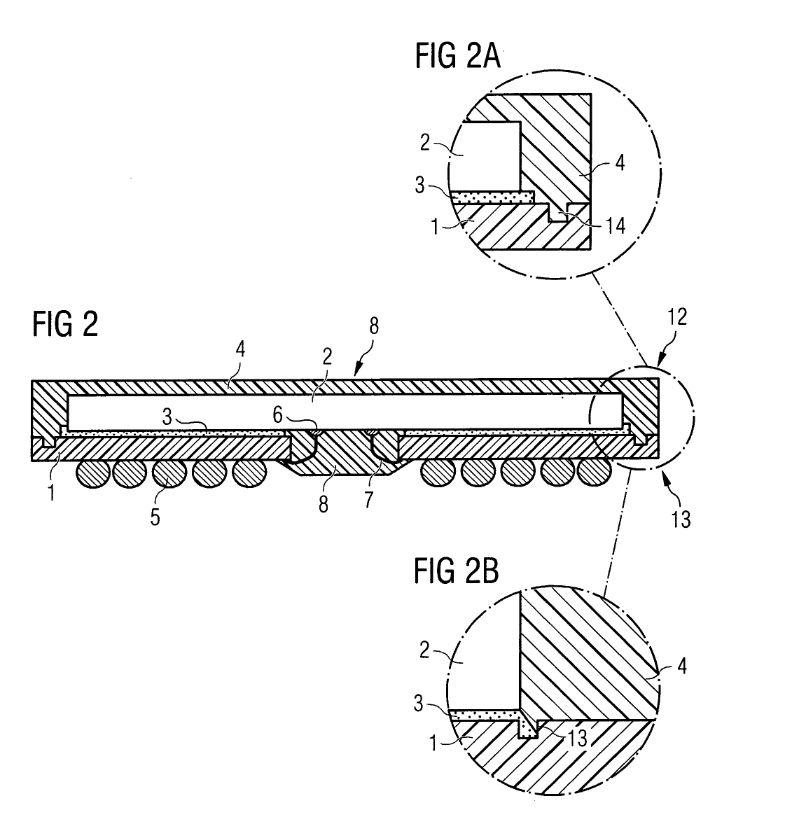

FIG. 2 depicts a BOC component similar to that of FIG. 1 with the substrate 1 on which a semiconductor chip 2 is adhered with an adhesive 3. As can be seen from FIG. 2, the adhesive 3 is somewhat larger than the semiconductor chip 2. For purposes of protection the chip 2 and the chip-side of the substrate 1 are covered by a mold cap 4. The mold cap 4 can be realized by use of a well-known encapsulation mold, which is pressed on the chip-side of the wafer and then filled with an encapsulation mold, also called a mold compound, thereby forming the mold cap 4.

To increase the adhesive power between the mold cap 4 and the substrate 1 on its rim portion 12, the chip-side surface of the substrate 1 is provided with grooves 13. These grooves 13 serve to increase the interface total surface area on the rim portion 12 of the substrate 1 and the mold cap 4. The grooves 13 serve as a reservoir enabling the mold compound to fill the grooves 13 during the encapsulation process. The result is a mold cap lock 14 projecting into the surface of the substrate 1. This can be seen best in FIG. 2A.

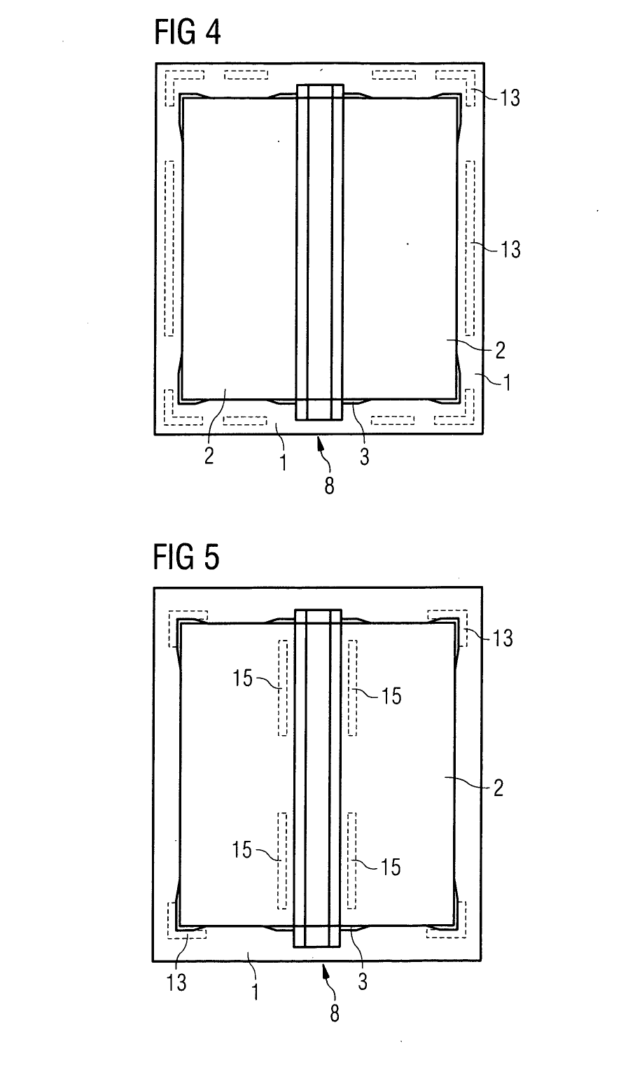

The grooves 13 can be placed at any place between the rim of the substrate and the rim of the semiconductor chip 2. FIGS. 2, 2A and 4 illustrate the position of the grooves 13 beside the rim of the semiconductor chip 2 and FIG. 5 closer to the rim of the semiconductor chip 2. FIGS. 4 and 5 show a chip-side top view illustrating possible positions of the grooves. For locking, the grooves 13 should be located at the component edge since it is the weakest point to be exposed to dicing when the component is singulated. FIG. 5 shows the grooves 13 in close position to the comers of the semiconductor chip 2 as another possibility.

The increased surface area will promote adhesion stability during the dicing process. Thus, higher feed speed can be considered. With reservoir ability, the filetting tolerance can be better controlled, thus will allow further component miniature design.

FIG. 2B illustrates a position of the groove 13 that is closer to the rim of the semiconductor chip 2 such that the groove is positioned partly below the adhesive 3 that extends over the rim of the semiconductor chip 2. Thereby it is enabled that, during the molding process, a part of the adhesive 3 can be pressed together with mold compound into the grooves 13. The groove 13 serving as a reservoir is thereby filled with adhesive and mold compound partly during the mold process. The result is a mold cap lock similar to that of FIG. 2A.

The grooves 13 can surround the whole circumference of the semiconductor chip 2 complete, in sections or at the corners only or in combination.

Further to FIG. 2, the substrate 1 has a ball side adjacent to the chip side and is provided with a wiring and ball pads (not shown) for receiving solder balls 5. In the center of the substrate exists an elongated bond channel 8, also indicated in FIGS. 4 and 5. The bond channel 8 is surrounded by sidewalls of the substrate 1 and the adhesive, which is something recessed between the semiconductor chip 2 and the substrate 1. This recess of the adhesive shall prevent bleeding of the adhesive 3 into the bond channel 8 during the die bonding process but cannot be prevented absolutely caused by the filetting tolerance and bonding pressure.

The bond channel 8 serves as a lead through for wire loops 7 to connect bond pads 6 on the semiconductor chip 2 with terminals of the wiring on the substrate 1 and thus connecting with the solder balls 5. The bond channel 8 is filled with a mold compound to protect the wire loops 7 before damage. This can be performed with a mold cap (not shown) having the negative form of the desired shape of the enclosure of the bond channel 8. The mold cap is pressed against the ball side of the substrate and filled with a mold compound and thus forming the bond channel enclosure by a well-known procedure.

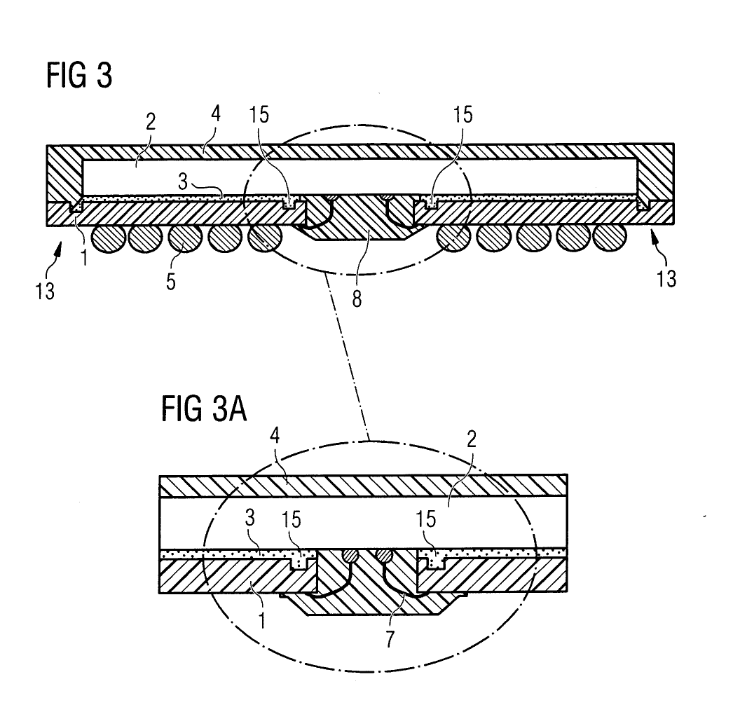

FIGS. 3 and 5 show a further embodiment of the invention with a so-called adhesive/epoxy reservoir 15. Details can be best seen from FIG. 3A. The adhesive/epoxy reservoir 15 in the substrate 1 has the same shape as the groove 13 but is positioned near the bond channel 8 underneath the adhesive 3. FIG. 3A shows an enlarged area with the bond channel 8 and of the reservoir 15 in the substrate 1. This reservoir 15 prevents the adhesive 3 from bleeding into the bond channel 8 during the chip bonding process and serves for a better contact between the mold compound 9 in the bond channel 8 and the substrate 1. The result is that a bond channel delamination is prevented.

The further construction is similar to that shown in FIGS. 2 and 2B, and, therefore, use the same reference numbers for the same feature. The semiconductor chip 2 is mounted onto the substrate 1 by way of the adhesive 3. On the chip-side of the substrate 1 exist the grooves 13, partly filled with adhesive and mold compound. The substrate 1 has a bond channel 8 filled with mold compound to protect the wire loops 7 drawn from bond pads 6 on the semiconductor chip 2 to terminals on the ball side of the substrate 1.

The grooves 13 and the reservoir 15 can be realized by grinding, milling, laser treatment or the like from the chip-side of the substrate 1, i.e., from its surface into its depth. These are well-known manufacturing steps, therefore, these steps are not described in detail.

The mentioned elongated grooves 13 and also the reservoir 15 can have a rectangular or any other cross section. Furthermore it is possible to use bores, holes or similar instead of the mentioned grooves 13, which are only an example for the best mode. The bores or holes should be positioned at the same places corresponding with the described position of the grooves.

What is claimed is:

1. A semiconductor component comprising:
a substrate having a chip side and a solder ball side;
a semiconductor chip mounted with an adhesive on the chip side of the substrate, said semiconductor chip being electrically conductively connected to a conductor structure of the substrate;
ball pads disposed over the solder ball side of the substrate, the ball pads electrically conductively connected to a conductor structure on the substrate and suitable for application of solder balls;
a bond channel formed within the substrate;
wire loops drawn from bond pads on the semiconductor chip to the conductor structure;
a reservoir disposed at a rim portion of the substrate; and
a sealing mold cap on the chip-side made of a mold compound, the sealing mold cap projecting into the reservoir.

2. The semiconductor component as claimed in claim 1, wherein the reservoir is positioned between an outer edge of the semiconductor chip and an outer edge of the substrate.

3. The semiconductor component as claimed in claim 1, wherein the reservoir has the shape of at least one elongated groove.

4. The semiconductor component as claimed in claim 3, wherein the reservoir has an approximately rectangular cross section.

5. The semiconductor component as claimed in claim 3, wherein the reservoir is filled with mold compound of the mold cap.

6. The semiconductor component as claimed in claim 2, wherein the reservoir is positioned closer to the outer edge of the semiconductor chip than the outer edge of the substrate.

7. The semiconductor component as claimed in claim 6, wherein the adhesive extends beyond the outer edge of the semiconductor chip.

8. The semiconductor component as claimed in claim 7, wherein the adhesive extends over the reservoir.

9. The semiconductor component as claimed in claim 8, wherein the adhesive extends at least partially within the reservoir.

10. The semiconductor component as claimed in claim 9, wherein the reservoir is filled partly with adhesive and mold compound.

11. The semiconductor component as claimed in claim 2, wherein the reservoir at least partially surrounds the circumference of the semiconductor chip.

12. The semiconductor component as claimed in claim 2, wherein the reservoir is arranged in close position to corners of the semiconductor chip.

13. The semiconductor component as claimed in claim 2, wherein the reservoir completely surrounds all edges of the semiconductor chip.

14. The semiconductor component as claimed in claim 2, wherein the reservoir surrounds the circumference of the semiconductor chip in sections.

15. The semiconductor component as claimed in claim 1, wherein the reservoir is positioned near the bond channel.

16. The semiconductor component as claimed in claim 15, wherein the reservoir has the shape of a groove.

17. The semiconductor component as claimed in claim 15, wherein the reservoir is arranged in parallel to the elongated bond channel.

18. The semiconductor component as claimed in claim 17, wherein the bond channel is filled with a mold compound.

19. The semiconductor component as claimed in claim 17, wherein the reservoir is filled with adhesive during chip bonding.

20. A method for producing a semiconductor component, the method comprising:
mounting a semiconductor chip on a chip side of a substrate;
electrically conductively connecting the semiconductor chip to a conductor structure of the substrate, the semiconductor chip being electrically conductively connected via wire loops that extend through a bond channel of the substrate;
applying solder balls on ball pads disposed over a solder ball side of the substrate;
providing a sealing mold cap on the chip-side made of a mold compound by a mold process, the mold process thereby filling a reservoir with mold compound, the reservoir disposed in the substrate adjacent an area where the semiconductor chip is mounted.

21. The method as claimed in claim 20, wherein the reservoir is positioned between an outer edge of the semiconductor chip and an outer edge of the substrate.

22. The method as claimed in claim 20, wherein the reservoir is formed in the shape of at least one elongated groove.

23. The semiconductor component as claimed in claim 22, wherein the reservoir has an approximately rectangular cross section.

24. The semiconductor component as claimed in claim 22, further comprising forming the at least one elongated groove by grinding.

25. The semiconductor component as claimed in claim 22, further comprising forming the at least one elongated groove by drilling.

26. The semiconductor component as claimed in claim 22, further comprising forming the at least one elongated groove by laser treatment.

27. The semiconductor component as claimed in claim 22, wherein the reservoir is filled with mold compound of the mold cap.

28. The semiconductor component as claimed in claim 21, wherein the reservoir is positioned closer to outer edge of the semiconductor chip than the outer edge of the substrate, the reservoir also being positioned below an adhesive used to mount the semiconductor chip.

29. The semiconductor component as claimed in claim 28, wherein the reservoir is filled partly with adhesive and partly with mold compound.

30. The semiconductor component as claimed in claim 21, wherein the reservoir at least partially surrounds the circumference of the semiconductor chip.

31. The semiconductor component as claimed in claim 21, wherein the reservoir is arranged in close position to corners of the semiconductor chip.

32. The semiconductor component as claimed in claim 21, wherein the reservoir completely surrounds the entire circumference of the semiconductor chip.

33. The semiconductor component as claimed in claim 21, wherein the reservoir surrounds the circumference of the semiconductor chip in sections.

34. The semiconductor component as claimed in claim 20, wherein the reservoir in the substrate is positioned adjacent the bond channel.

35. The semiconductor component as claimed in claim 34, wherein the reservoir has the shape of a groove.

36. The semiconductor component as claimed in claim 34, wherein the reservoir is arranged in parallel to the elongated bond channel.

37. The semiconductor component as claimed in claim 36, wherein the bond channel is filled with a mold compound.

38. The semiconductor component as claimed in claim 35, wherein the reservoir is filled with an adhesive during chip mounting.
